(19) United States
(12) Patent Application Publication
(10) Pub. No.: US 2024/0349613 A1
(43) Pub. Date: Oct. 17, 2024

(54) CRYSTAL VIBRATION ELEMENT AND CRYSTAL DEVICE

(71) Applicant: KYOCERA Corporation, Kyoto-shi, Kyoto (JP)

(72) Inventors: Masahiko GOTO, Tendo-shi (JP); Masatoshi YUMURA, Yamagata-shi (JP); Tsuyoshi NITOBE, Higashine-shi (JP)

(73) Assignee: KYOCERA Corporation, Kyoto-shi, Kyoto (JP)

(21) Appl. No.: 18/682,641

(22) PCT Filed: Aug. 8, 2022
(86) PCT No.: PCT/JP2022/030212

§ 371 Date: Feb. 9, 2024

(30) Foreign Application Priority Data
Aug. 26, 2021 (JP) 2021-137676

(51) Int. Cl. H10N 30/87; H10N 30/88

(52) U.S. Cl. CPC H10N 30/87; H10N 30/88

(57) ABSTRACT

A crystal vibration element includes a crystal piece with an oscillation frequency in a range of 50 MHz or higher and 100 MHz or lower and excitation electrodes positioned on opposite surfaces of the crystal piece in a one-to-one relation, the excitation electrodes each having a rectangular shape in a plan view and being smaller than the crystal piece. A length of each of the excitation electrodes in a first direction along a direction of an electrical axis of the crystal piece in the plan view is 1.993 or more and 2.525 or less times a width of each excitation electrode in a second direction perpendicular to the first direction.

### TECHNICAL FIELD

The present disclosure relates to a crystal vibration element and a crystal device.

### BACKGROUND OF INVENTION

A crystal vibration element for generating a clock signal by causing a crystal piece to oscillate can provide an oscillation frequency depending on a thickness of the crystal piece. Recently, with a rise in required frequency of the clock signal, the crystal vibration element in a band from 50 to 100 MHz with a nominal frequency of 76.8 MHz has been used in an increasing number. Japanese Unexamined Patent Application Publication No. 2020-99038 discloses a technique of forming a fixed portion of the crystal piece to be thicker than a vibrating portion and appropriately determining a ratio of a long side dimension to a short side dimension of the vibrating portion with the intent to obtain more satisfactory oscillation frequency characteristics at the above-mentioned frequency.

### SUMMARY

An embodiment of the present disclosure provides a crystal vibration element including:
a crystal piece with an oscillation frequency in a range of 50 MHz or higher and 100 MHz or lower; and
electrodes positioned on opposite surfaces of the crystal piece in a one-to-one relation, each electrode of the electrodes having a rectangular shape in a plan view and being smaller than the crystal piece,
wherein a length of the each electrode in a first direction along an X-axis direction of the crystal piece in the plan view is 1.993 or more and 2.525 or less times a width of the each electrode in a second direction perpendicular to the first direction.

### BRIEF DESCRIPTION OF THE DRAWINGS

FIG. 1 illustrates a shape of a crystal device according to an embodiment when viewed in a certain cross-section.

FIG. 2A is a plan view illustrating a configuration of a crystal vibration element according to the embodiment.

FIG. 2B is a sectional view of the crystal vibration element.

FIG. 2C is a side view of the crystal vibration element.

FIG. 3A illustrates an example of an aspect ratio of an excitation electrode.

FIG. 3B illustrates an experimental result of temperature characteristics of a frequency deviation depending on the aspect ratio of the excitation electrode.

FIG. 3C illustrates an experimental result of temperature characteristics of ESR (Equivalent Serial Resistance) depending on the aspect ratio of the excitation electrode.

FIG. 4A illustrates an example of the aspect ratio of the excitation electrode.

FIG. 4B illustrates an experimental result of the temperature characteristics of the frequency deviation depending on the aspect ratio of the excitation electrode.

FIG. 4C illustrates an experimental result of the temperature characteristics of the ESR depending on the aspect ratio of the excitation electrode.

FIG. 5A illustrates an example of the aspect ratio of the excitation electrode.

FIG. 5B illustrates an experimental result of the temperature characteristics of the frequency deviation depending on the aspect ratio of the excitation electrode.

FIG. 5C illustrates an experimental result of the temperature characteristics of the ESR depending on the aspect ratio of the excitation electrode.

FIG. 6A illustrates an example of the aspect ratio of the excitation electrode.

FIG. 6B illustrates an experimental result of the temperature characteristics of the frequency deviation depending on the aspect ratio of the excitation electrode.

FIG. 6C illustrates an experimental result of the temperature characteristics of the ESR depending on the aspect ratio of the excitation electrode.

FIG. 7A illustrates an example of the aspect ratio of the excitation electrode.

FIG. 7B illustrates an experimental result of the temperature characteristics of the frequency deviation depending on the aspect ratio of the excitation electrode.

FIG. 7C illustrates an experimental result of the temperature characteristics of the ESR depending on the aspect ratio of the excitation electrode.

### DESCRIPTION OF EMBODIMENTS

An embodiment will be described below with reference to the drawings.

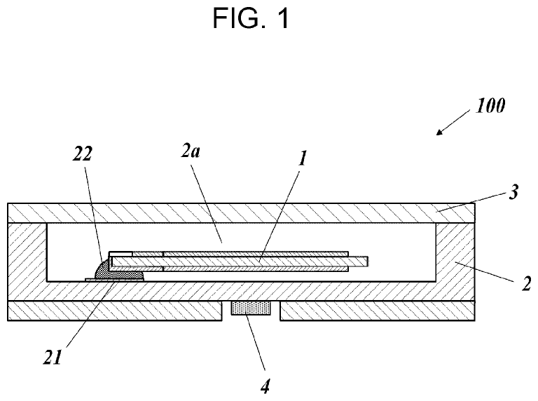

FIG. 1 illustrates a shape of a crystal device 100 according to the embodiment when viewed in a certain cross-section.

The crystal device 100 includes a crystal vibration element 1, a base member 2, a cover member 3, a component 4, and so on.

The base member 2 is made of, for example, a ceramic material, a semiconductor material, a glass material, or a combination of those materials although not particularly limited to the above-mentioned examples. The base member 2 includes a recess 2a at a center of an upper surface. Electrode pads 21 are each positioned on a bottom surface of the recess 2a and has a flat upper surface. The electrode pad 21 may be formed by, for example, screen printing. An uppermost surface of the electrode pad 21 may be gold-plated, for example. The crystal vibration element 1 is bonded to the electrode pad 21 with a conductive adhesive 22. The conductive adhesive 22 may be, for example, an adhesive made of resin (epoxy resin or the like) containing silver filler. A vibrating (oscillating) portion of the crystal vibration element 1 is fixedly held in a floating state without contacting an inner wall surface of the recess 2a.

An end of the base member 2 on the upper side of the recess, namely an upper end of a frame portion of the base member 2 surrounding the recess 2a, is joined to the cover member 3 with a conductive sealing material, such as gold tin or silver wax, interposed between them. With that arrangement, the recess 2a is sealed off. A metallized conductive layer in a frame shape may be positioned between the base member 2 and the cover member 3.

The electrode pad 21 can be electrically connected to the outside via a signal line (not illustrated) penetrating through the base member 2 (in an example, the electrode pad 21 can be connected to an external wiring or substrate from an external connection pad that is positioned at a bottom surface of the base member 2). The component 4 is positioned on the bottom surface side of the base member 2. The component 4 may be an electronical component such as an IC chip, or a sensor such as a temperature measurement element (for example, a thermistor). In another example, the component 4 may be a combination of those components. Those components have the function of outputting additional information in relation to adjustment of an oscillation frequency of the crystal vibration element 1 or the function of performing adjustment in response to the additional information. Thus, the crystal device 100 may be, for example, a temperature compensated crystal oscillator (TCXO). It is to be noted that the component 4 may be disposed at an off-center position of the bottom surface instead of being disposed at the center or thereabout in a plan view.

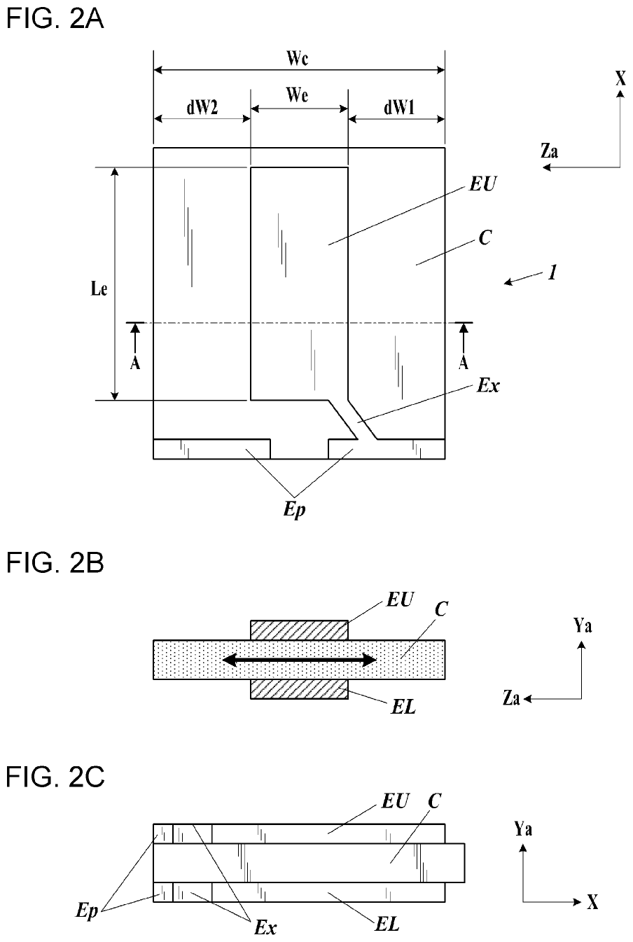

FIG. 2A is a plan view illustrating a configuration of the crystal vibration element 1 according to the embodiment. FIG. 2B is a sectional view taken along a section line AA in FIG. 2A. FIG. 2C is a side view of the crystal vibration element 1.

The crystal vibration element 1 includes a crystal piece C, excitation electrodes EU and EL (electrodes), lead-out lines Ex (lead-out conductors), and connection electrodes Ep, the latter threes being positioned on opposite surfaces of the crystal piece C in a one-to-one relation.

The crystal piece C is an AT-cut crystal piece, and its thickness is determined corresponding to the oscillation frequency in a range of 50 MHz or higher and 100 MHz or lower, particularly here in a range of 74 MHz or higher and 78 MHz or lower such that a nominal frequency of 76.8 MHz is obtained. In general, as illustrated in FIGS. 2A and 2C, a direction (first direction) along a crystal axis (electrical axis) of a quartz crystal is assumed to be an X axis. A direction along an optical axis of the quartz crystal is assumed to be a Z axis. As illustrated in FIG. 2A, a direction (second direction) crossing the X axis within a plane of the crystal piece C is assumed to be a Za axis (also often referred to as a Z′ axis). A direction crossing the X axis and the Za axis (namely, a thickness direction of the crystal piece C) is a Ya-axis direction. Here, the X-axis direction is a long axis direction of the crystal piece C, and the Za-axis direction is a short axis direction of the crystal piece C.

The excitation electrodes EU and EL are joined respectively to an upper surface (+Ya side) and a lower surface (−Ya side) of the crystal piece C at the same position in the plan view. The crystal piece C deforms and vibrates corresponding to a voltage applied between the excitation electrodes EU and EL. Here, a vibration mode of the crystal piece C is thickness shear vibration, and the crystal piece C displaces in opposite phases in the X-axis direction between the upper surface side and the lower surface side. The excitation electrodes EU and EL each have a rectangular shape in the plan view and have a smaller size than the crystal piece C. The meaning of the wording “rectangular shape in the plan view” used here is not limited to the case of a complete rectangular shape. For example, corners of the excitation electrodes EU and EL may be slightly chipped or rounded.

The lead-out lines Ex are linear wirings for electrical connection between the excitation electrodes EU and EL and the connection electrodes Ep. The lead-out lines Ex are positioned on an upper surface and a lower surface of the crystal piece C in a one-to-one relation to the excitation electrodes EU and EL.

The connection electrodes Ep are connected to the electrode pads 21 of the base member 2 in a one-to-one relation. During operation of the crystal vibration element 1, a predetermined potential difference is applied between the connection electrodes Ep from the outside. This causes the crystal vibration element 1 to resonate, whereby a clock signal of a predetermined frequency (about 76.8 MHz) is obtained from a crystal oscillation circuit to which the crystal vibration element 1 is connected.

As described above, the excitation electrodes EU and EL each have the smaller size than the crystal piece C in the plan view. For the range from 50 to 100 MHz including the oscillation frequency of the crystal vibration element 1, the crystal vibration element has been designed in the past such that a vibration region of the crystal piece C in the plan view is substantially in match with a region of each of the excitation electrodes EU and EL. However, because of temperature characteristics being greatly different between the quartz crystal and the electrode metal, if the crystal vibration element operates at a temperature deviated from the reference temperature, distortion of the electrode affects vibration of the quartz crystal and deteriorates (raises) the temperature characteristics in relation to resonance, particularly ESR (Equivalent Serial Resistance: also referred to as CI (Crystal Impedance)). According to this embodiment, in the crystal vibration element 1, influences of the excitation electrodes EU and EL upon the crystal piece C are reduced relatively by reducing the sizes of the excitation electrodes EU and EL.

On the other hand, when the regions of the excitation electrodes EU and EL are made smaller than the vibration region in the X-axis direction, a voltage (power) necessary to obtain a required resonance wave is increased, and power consumption efficiency is reduced. In the crystal vibration element 1 according to this embodiment, the influence upon generation of the resonance wave and the influence of a difference in temperature characteristics between each of the excitation electrodes EU and EL and the crystal piece C upon the resonance are both suppressed by reducing the size of the vibration region only in the Za-axis direction without significantly changing a length of each of the excitation electrodes EU and EL in the X-axis direction (while a small change in terms of design (for example, several percentage (%) may be allowable).

Here, a ratio of the length of the excitation electrodes EU and EL along the X-axis direction (length Le in a longitudinal direction) to a width in the Za-axis direction (transverse width We) (namely, an aspect ratio Le/We) is 1.993 or more and 2.525 or less. In particular, the ratio is set to 2.33. The aspect ratio Le/We of the excitation electrodes EU and EL formed in match with the vibration region of the crystal piece C as described above is about 1.25. In contrast, in the crystal vibration element 1, the length of the excitation electrodes EU and EL is significantly longer than that in the above case. It is to be noted that, in related-art crystal vibration elements, the length Le of the excitation electrodes EU and EL is not so different from a length of the crystal piece C in the longitudinal direction (X direction), and that increasing the length Le of the excitation electrodes EU and EL, smaller than that of the crystal piece C, to increase the aspect ratio Le/We is not to be supposed here. In addition, since the aspect ratio Le/We is changed with the intent to reduce the sizes of the excitation electrodes EU and EL, an increase in the length Le is not desired.

Thus, as described above, shapes of the excitation electrodes EU and EL are only changed to reduce their sizes, and the size of the vibration region of the crystal piece C is not reduced. Accordingly, the transverse width Wc of the crystal piece C is maintained substantially the same as the size in the related art, while spacings dW1 and dW2 between long sides of each of the excitation electrodes EU and EL and long sides of the crystal piece C (namely distances from opposite ends of the crystal piece C extending in the X-axis direction to each of the excitation electrodes EU and EL) are increased in comparison with those in the related art. The excitation electrodes EU and EL are preferably positioned near a center position (midpoint) of the crystal piece C in the Za-axis direction, and hence the spacings dW1 and dW2 are substantially equal to each other (namely, a half of the difference between the transverse width Wc and the transverse width We). However, the excitation electrodes EU and EL may be slightly deviated from the center position of the crystal piece C in the Za-axis direction as far as the deviation does not adversely affect the resonance. Here, the spacings dW1 and dW2 are equal values in a range of 0.130 mm or more and 0.195 mm or less.

With respect to the above-described structure, the lead-out lines Ex are led out (or connected) at their one ends from (or to) the short sides of the excitation electrodes EU and EL (namely, outer edges thereof extending in the Za-axis direction) and are connected at their opposite ends to the connection electrodes Ep, respectively, such that an influence upon the vibration of the crystal piece C is reduced. Here, the lead-out lines Ex each have a linear shape. As the lead-out line Ex is shorter, the influence upon the vibration of the crystal piece C can be made smaller. Although the lead-out line Ex extends obliquely at a predetermined angle relative to the short sides of the excitation electrodes EU and EL, an inclination angle is not limited to the illustrated one. As far as any problem, such as a short circuit with another conductor, does not occur in a manufacturing process, the inclination angle may be smaller than the illustrated one or may be perpendicular to the short sides of the excitation electrodes EU and EL.

The above-described structure can stabilize oscillation efficiency and the temperature characteristics of the crystal vibration element 1 according to this embodiment.

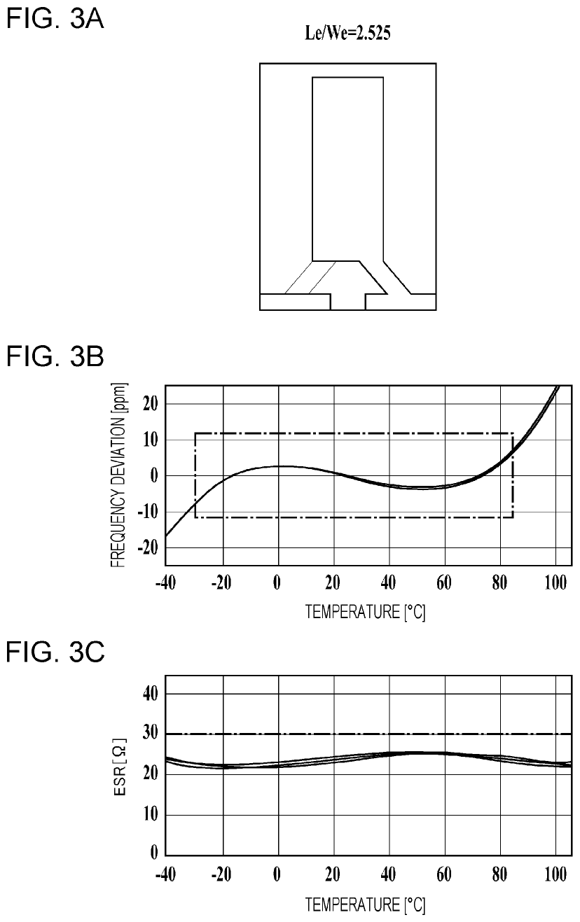

FIGS. 3A to 3C, FIGS. 4A to 4C, FIGS. 5A to 5C, FIGS. 6A to 6C, and FIGS. 7A to 7C illustrate experimental results of temperature characteristics [ppm] of a frequency deviation (df/f) (FIGS. 3B to 7B) and temperature characteristics [Ω] of the ESR (FIGS. 3C to 7C) when the aspect ratio Le/We of the excitation electrodes EU and EL is set to different values (FIGS. 3A to 7A). In the drawings, the results are obtained by repeating an experiment three times for each value of the ratio Le/We and are represented in a superimposed fashion.

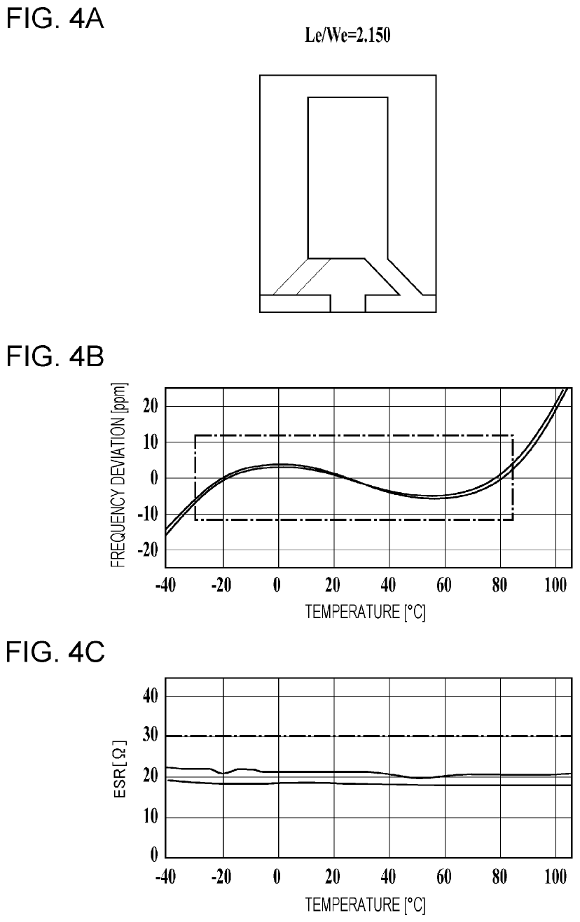

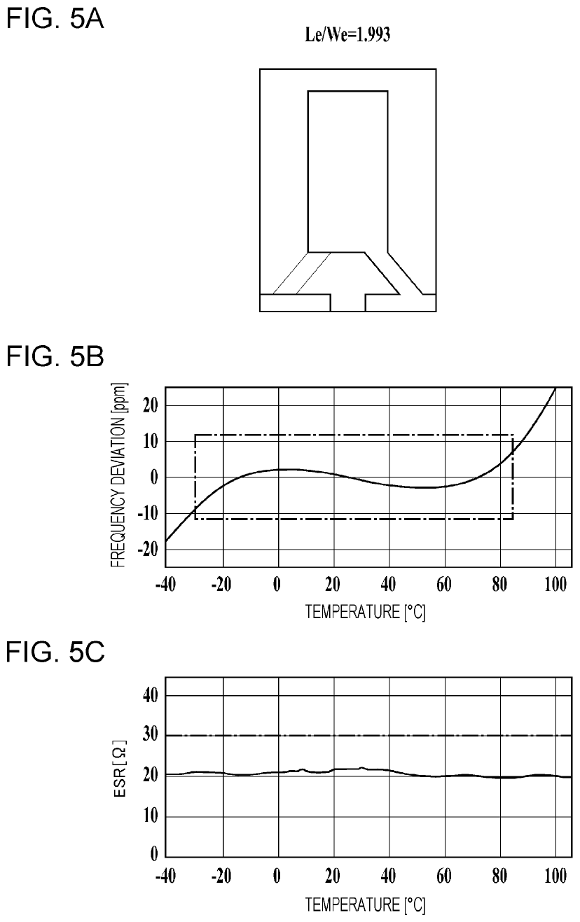

In the case of Le/We=from 2.150 to 1.993 illustrated in FIGS. 4A and 5A, the temperature characteristics of the frequency deviation is represented by a substantially balanced cubic function as illustrated in FIGS. 4B and 5B, and the ESR is maintained at about 25Ω or less substantially regardless of temperature as illustrated in FIGS. 4C and 5C. It is hence understood that the crystal vibration element 1 can appropriately generate resonance in a practically required temperature range. When the aspect ratio Le/We increases as illustrated in FIG. 3A, the Equivalent serial resistance value causes a deflection and sometimes exceeds 25Ω as illustrated in FIGS. 3B and 3C, but it is maintained at a value less than 30Ω, which is a general reference value for products, as far as the aspect ratio Le/We is in a range of 2.525 or less.

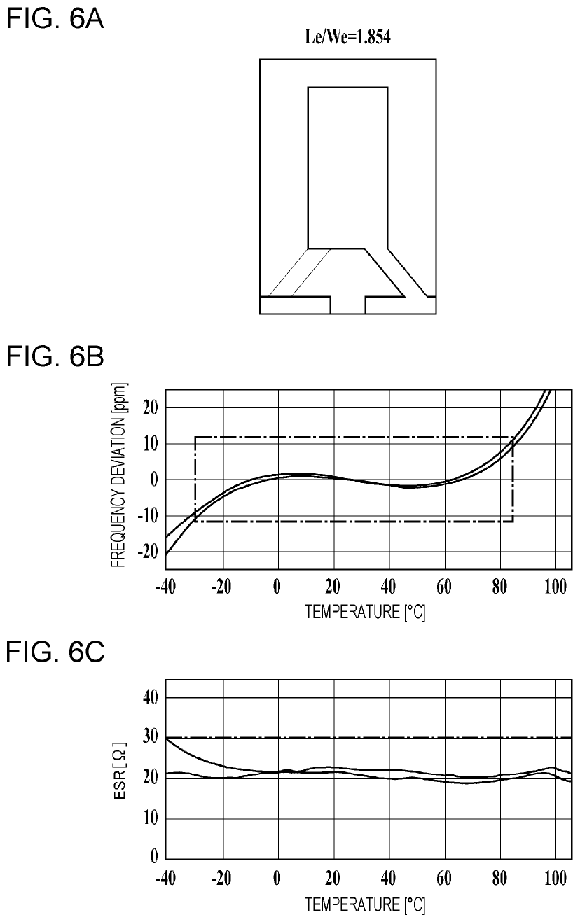

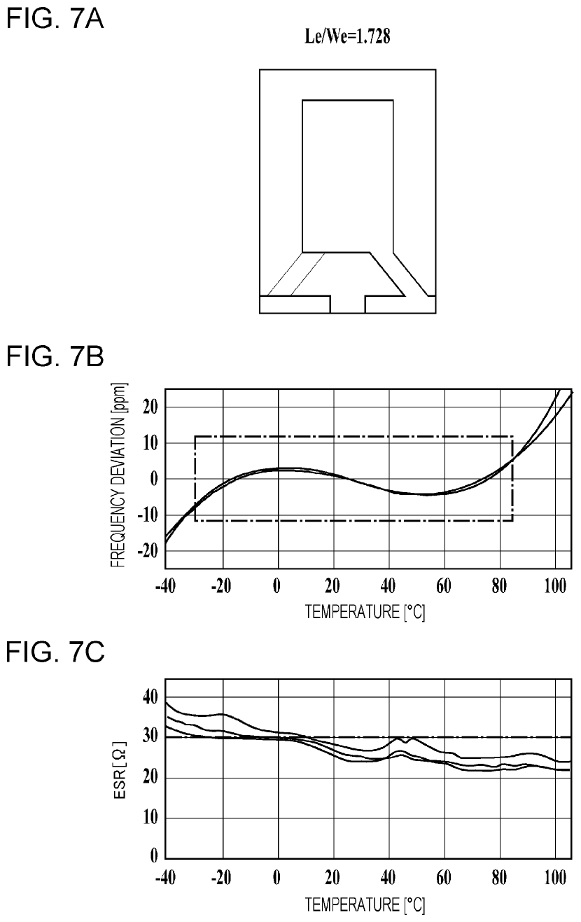

On the other hand, when the aspect ratio Le/We decreases as illustrated in FIGS. 6A and 7A, this leads to a result that the serial resistance value increases particularly on the lower temperature side and reaches 30Ω as illustrated in FIGS. 6B, 6C, 7B, and 7C. Thus, the crystal vibration element 1 can provide good temperature characteristics in a range (1.993≤Le/We≤2.525) in which the aspect ratio of the excitation electrodes EU and EL is significantly greater than that in the related art. If the aspect ratio Le/We deviates from the above range, the temperature characteristics deteriorate due to particularly an increase in the ESR and so on.

As described above, according to this embodiment, the crystal vibration element 1 includes the crystal piece C with the oscillation frequency in the range of 50 MHz or higher and 100 MHz or lower and the excitation electrodes EU and EL positioned on the opposite surfaces of the crystal piece C in a one-to-one relation, those excitation electrodes EU and EL each having the rectangular shape in the plan view and being smaller than the crystal piece C. The length Le of each of the excitation electrodes EU and EL in the first direction along the direction of the X axis (electrical axis) of the crystal piece C in the plan view is 1.993 or more and 2.525 or less times the width (transverse width We) of each excitation electrode in the second direction (Za-axis direction) perpendicular to the first direction.

In the crystal vibration element with the oscillation frequency in the range from 50 to 100 MHz, Le/We is usually about 1.25, and the sizes of the excitation electrodes EU and EL are set substantially in match with the vibration region of the crystal piece C. In contrast, in the crystal vibration element 1 according to this embodiment, the sizes of the excitation electrodes EU and EL are each reduced by intentionally reducing the transverse width We in comparison with the length Le and by setting Le/We to a larger value. It is hence possible to reduce an influence of the difference in thermal expansion coefficient between each of the excitation electrodes EU and EL and the crystal piece C, to suppress deterioration of the temperature characteristics in relation to the oscillation of the crystal vibration element 1, and to generate more stable oscillation while a reduction in an excitation level is suppressed.

The oscillation frequency is particularly desired to fall in the range of 74 MHz or higher and 78 MHz or lower. In other words, the configuration of the present disclosure is preferably applied to the crystal vibration element 1 with the nominal frequency of 76.8 MHz, for example.

In the crystal vibration element 1, the distances from the opposite ends of the crystal piece C to the ends of each of the excitation electrodes EU and EL in the second direction (Za-axis direction) in the plan view are each 0.130 mm or more and 0.195 mm or less. In other words, since the excitation electrodes EU and EL are positioned substantially at the center of the crystal piece C in the Za-axis direction, part of the vibration region of the crystal piece C, the part extending (or positionally leaking) out from the region of the excitation electrodes EU and EL in the Za-axis direction, is suppressed from reaching the above-mentioned opposite ends of the crystal piece C, the oscillation of the crystal piece C is not impeded, and the crystal vibration element 1 can be efficiently oscillated.

The crystal vibration element 1 further includes the lead-out lines Ex connected at respective one ends thereof to the outer edges (short sides) of the excitation electrodes EU and EL, those outer edges extending along the second direction (Za-axis direction). Thus, since the vibration region of the crystal piece C extends out from the long sides of the excitation electrodes EU and EL but hardly extends out from the short sides of the excitation electrodes EU and EL, an adverse influence of the lead-out lines Ex upon the vibration can be reduced by leading out the lead-out lines Ex from the short sides of the excitation electrodes EU and EL.

The lead-out lines Ex each have a linear shape. As the lead-out line Ex is shorter, the vibration of the crystal piece C is less affected, and less mixing of external noise, for example, can be realized. For that reason, the lead-out line Ex preferably has the linear shape.

According to this embodiment, the crystal device 100 includes the crystal vibration element 1 described above. The crystal device 100 enables the crystal vibration element 1 to oscillate with more stable and satisfactory temperature characteristics than in the related art and to provide an appropriate signal.

The above-described embodiment is merely an example and can be modified in various ways.

For example, while the above embodiment has been described in connection with the crystal device 100 including the component 4, the crystal device 100 is not always required to include the component 4. The crystal device 100 may be a crystal package that simply includes a base member and a cover member, and that just outputs a signal. In another example, the crystal vibration element 1 does not need to be bonded to the base member 2 for constituting the crystal device 100. The crystal vibration element 1 may be, for example, sold alone separately.

The shapes of the base member 2 and the cover member 3 (including the shape of the recess 2a) may be changed as appropriate to be able to properly store and seal the crystal vibration element 1 and to arrange signal lines and the electrode pads 21 at proper positions. The shape of the crystal piece C may also be finely adjusted, for example, in thickness of its end portions. Furthermore, while the crystal piece C has been described above in connection with an example in which the vibrating portion where the excitation electrodes EU and EL are positioned and a fixed portion where the connection electrodes Ep are positioned have the same thickness (a flat shape), the thickness of the fixed portion may be set to be greater than that of the vibrating portion (to provide a step shape) such that the crystal piece C can be more stably supported.

The shape of the lead-out lines Ex is not limited to the one described in the above embodiment. The lead-out lines Ex may include bent portions or curved portions and are not always required to be led out from the short sides of the excitation electrodes EU and EL.

The above embodiment has been described in connection with an example in which the nominal frequency is 76.8 MHz. However, since the above-described features in relation to the shape of the excitation electrodes EU and EL are effective as far as the oscillation frequency is in the range from 50 to 100 MHz, the crystal vibration element 1 may oscillate a signal of another frequency within that range.

In addition, the specific configurations, structures, materials, and so on described in the above embodiment can be modified as appropriate as far as not departing from the gist of the present disclosure. The scope of the present invention includes not only the scope defined in Claims, but also the scope equivalent to the former.

### INDUSTRIAL APPLICABILITY

The present disclosure can be applied to a crystal vibration element and a crystal device.

1. A crystal vibration element comprising:
a crystal piece with an oscillation frequency in a range of 50 MHz or higher and 100 MHz or lower; and
electrodes positioned on opposite surfaces of the crystal piece in a one-to-one relation, each electrode of the electrodes having a rectangular shape in a plan view and being smaller than the crystal piece,
wherein a length of each electrode in a first direction along an X-axis direction of the crystal piece in the plan view is 1.993 or more and 2.525 or less times a width of the each electrode in a second direction perpendicular to the first direction.

2. The crystal vibration element according to claim 1,
wherein the oscillation frequency is in a range of 74 MHz or higher and 78 MHz or lower.

3. The crystal vibration element according to claim 1,
wherein distances from opposite ends of the crystal piece to ends of each electrode in the second direction in the plan view are 0.130 mm or more and 0.195 mm or less.

4. The crystal vibration element according to claim 1,
further comprising a lead-out conductor connected to an outer edge of each electrode, the outer edge extending along the second direction.

5. The crystal vibration element according to claim 4,
wherein the lead-out conductors each have a linear shape.

6. A crystal device comprising the crystal vibration element according to claim 1.

7. A crystal device comprising:
a crystal vibration element having
a crystal piece with an oscillation frequency in a frequency range; and
at least one electrode pair positioned opposite each other on opposite surfaces of the crystal piece, each electrode of the at least one electrode pair having a rectangular shape in a plan view that is smaller than the crystal piece,
wherein a length of each electrode in a first direction along an X-axis direction of the crystal piece in the plan view is 1.993 or more and 2.525 or less times a width of each electrode in a second direction perpendicular to the first direction, and
wherein the frequency range is between 50 MHz and 100 MHZ, inclusive, or between 74 MHz and 78 MHz, inclusive.
